(19) United States
(12) Patent Application Publication
(10) Pub. No.: US 2005/0016576 A1
(43) Pub. Date: Jan. 27, 2005

(54) STACKED THERMOCOUPLE STRUCTURE AND SENSING DEVICES FORMED THEREWITH

(75) Inventors: Qin Jiang, Kokomo, IN (US); Han S. Lee, Bloomfield Hills, MI (US); James H. Logsdon, Kokomo, IN (US); Dan W. Chilcott, Greentown, IN (US); David K. Lambert, Sterling Heights, MI (US); Shih-Chia Chang, Bloomfield Hills, MI (US)

Correspondence Address: HARTMAN & HARTMAN, P.C., 552 EAST 700 NORTH, VALPARAISO, IN, 46383, US

(73) Assignee: DELPHI TECHNOLOGIES, INC., Kokomo, IN (US)

(21) Appl. No.: 10/710,250

(22) Filed: Jun. 29, 2004

Related U.S. Application Data
(60) Provisional application No. 60/489,727, filed on Jul. 24, 2003.

(51) Int. Cl. H01L 35/00; H01L 35/30; H01L 37/00; H01L 35/28

(52) U.S. Cl. 136/224

(57) ABSTRACT

A thermocouple structure capable of providing a more compact thermopile-based thermal sensor. The thermocouple structure has a stacked configuration that includes a plurality of first conductors on a surface, a dielectric layer on each of the first conductors, and a plurality of second conductors on the dielectric layer and formed of a different material than the first conductors. Each first conductor has first and second ends, and each second conductor has a first end overlying and contacting the first end of one of the first conductors, and a second end overlying but separated from the second end of the first conductor by the dielectric layer. A plurality of third conductors electrically interconnect one of the second ends of the second conductors with one of the second ends of the first conductors. Each third conductors is thicker than the second conductors to promote the robustness of the connection.

### CROSS REFERENCE TO RELATED APPLICATIONS

This application claims the benefit of U.S. Provisional Application No. 60/489,727, filed Jul. 24, 2003.

### BACKGROUND OF INVENTION

1. Field of the Invention

The present invention generally relates to thermocouple materials and processes, and more particularly to a thermocouple configuration capable of providing a compact thermopile-based thermal sensor.

2. Description of the Related Art

It is well known in the art to sense and measure temperature with thermocouples. An example is infrared sensors that make use of thermopiles. A thermopile comprises a series of connected thermocouples, each made up of dissimilar electrically-resistive materials such as semiconductors and metals, and converts thermal energy into an electric voltage by a mechanism known as the Seebeck effect. The general structure and operational aspects of thermopiles are well known and therefore will not be discussed in any detail here.

FIG. 1 represents a plan view of a portion of a thermocouple array 110, wherein alternating lines 112 and 114 formed of different electrically-conductive materials are connected at one end to form hot junctions 116, and at their opposite ends to form reference temperature junctions, or “cold” junctions 118. If a temperature difference exists between the hot and cold junctions 116 and 118, an open circuit voltage is generated at the two unconnected ends of the array 110.

Typically, adjacent pairs of the different conductors 112 and 114 are laid side by side and separated by a dielectric layer 120, as shown in FIG. 1. An increase in the thermal resistance of the conductors 112 and 114 corresponds to an increase in the output from the thermocouples. In the case where polycrystalline silicon (poly-Si) and aluminum are used as the materials for the two thermocouple conductors 112 and 114, the thermal resistance of aluminum is about ten times lower than that of poly-Si, such that it is important to minimize the thickness and transverse width of the aluminum conductors (e.g., 114) to maximize their thermal resistance. Reducing the cross-section of the aluminum conductors 114 is also very beneficial for controlling and limiting conductive heat loss through the aluminum conductors 114. As evident from FIG. 2, in the side-by-side structure of FIG. 1, the aluminum conductors 114 are required to traverse steps formed by the dielectric layer 120 and the poly-Si conductor 112. The aluminum conductors 114 are typically formed to be at least as thick as the poly-Si conductors 112 in order to reduce the risk of breakage of the conductors 114, which would result in the loss of electrical continuity.

In view of the above, it can be appreciated that the output of a thermopile is limited by the requirement for robust conductor layers that resist breakage, and that it would be desirable if increased output were possible without reducing the reliability of the thermopile.

### SUMMARY OF INVENTION

The present invention is directed to a stacked thermocouple structure whose configuration is capable of increased output without reducing the reliability of the thermocouple or a sensing device such as a thermopile-based thermal sensor in which the thermocouple structure is used. In so doing, the thermocouple structure is also capable of providing a more compact thermopile-based thermal sensor.

Generally, the stacked thermocouple structure includes a plurality of first conductors on a surface, a dielectric layer on each of the first conductors, and a plurality of second conductors on the dielectric layers. The first and second conductors are formed of a different material to define a thermocouple. Each first conductor has first and second ends, and each second conductor has a first end overlying and contacting the first end of one of the first conductors and a second end overlying but separated from the second end of the first conductor by the dielectric layer. A plurality of third conductors electrically interconnect the second ends of the second conductors with the second ends of adjacent first conductors. Each third conductors is thicker than the second conductors, with the result that the reliability of the connections made with the third conductors is promoted while permitting the size of the second conductors to be minimized.

As described above, the stacked thermocouple structure of this invention can be used in a thermopile capable of producing a larger output signal as a result of the minimal thickness of the second conductors. Simultaneously, the thicker third conductors are more capable than the thinner second conductors of negotiating steps defined by and between the first and second conductors, such that the risk of losing continuity of the thermopile is significantly reduced. By forming the hot junctions with the thinner second connectors and limiting the thicker third connectors to the cold junctions, the thermocouple structure of this invention is also able to exhibit reduced heat loss. The ability to more closely pack stacked thermocouple pairs in a given area than traditional side-by-side thermocouple structures provides another advantage by further promoting the generation of a higher output signal for a given surface area.

Other objects and advantages of this invention will be better appreciated from the following detailed description.

### BRIEF DESCRIPTION OF DRAWINGS

FIG. 1 represents a plan view of a portion of a thermocouple array formed of alternating lines of different electrically-conductive materials in accordance with the prior art.

FIG. 2 is a cross-sectional view along line 2-2 of the thermocouple array of FIG. 1.

FIG. 3 represents a plan view of a portion of a thermocouple array in accordance with an embodiment of the present invention.

FIGS. 4, 5, 6 and 7 are cross-sectional views along lines 4-4, 5-5, 6-6, and 7-7, respectively, of the thermocouple array of FIG. 3.

### DETAILED DESCRIPTION

As represented in FIGS. 3 through 7, the present invention provides a thermocouple structure 10 of a type suitable for use in a thermopile of an infrared sensor, such as the sensors disclosed in commonly-assigned U.S. patent application Ser. Nos. 10/065,447 and 10/065,448, the contents of which relating to thermopile construction are incorporated herein by reference. The thermocouple structure 10 is shown as comprising first and second conductors 12 and 14 that are stacked on a dielectric layer 20 on a substrate surface 22. The first conductors 12 can be seen as wider than the second conductors 14, with each conductor 12 and 14 forming a leg of the thermocouple structure 10. Though not limited to any particular materials, preferred materials for the first and second conductors 12 and 14 are polysilicon (poly-Si) and aluminum, respectively.

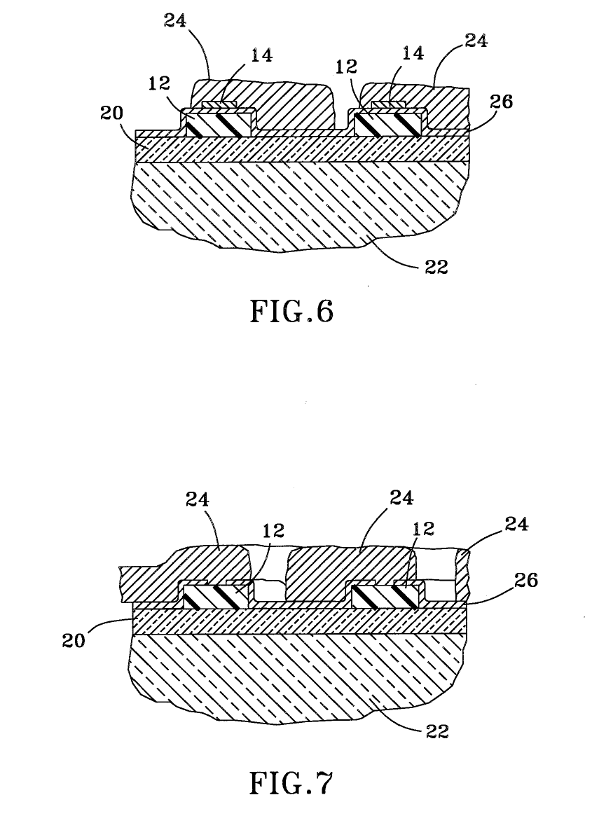

As seen in FIG. 4, the conductors 12 and 14 physically contact each other to form one junction 16 of each thermocouple pair, but are otherwise separated from each other by a thin dielectric layer 26 as seen in FIGS. 5 and 6. Interconnection of the first and second conductors 12 and 14 at the opposite end of each adjacent thermocouple pair is through a connector 24, thereby forming the second junction 18 of the thermocouples. The connectors 24 are preferably formed of the same material (e.g., aluminum) as the second conductors 14. In addition, the connectors 24 are preferably thicker than the second conductors 14 in order to reliably negotiate steps defined by the dielectric layer 26 and conductors 12 and 14 (FIGS. 6 and 7) with reduced risk of breakage. While the junctions 18 at which the connectors 24 are located may be either the hot or cold junctions of the thermocouple structure 10, the junctions 18 at which the thicker connectors 24 are located are preferably the cold junctions of the structure 10 to minimize the heat loss.

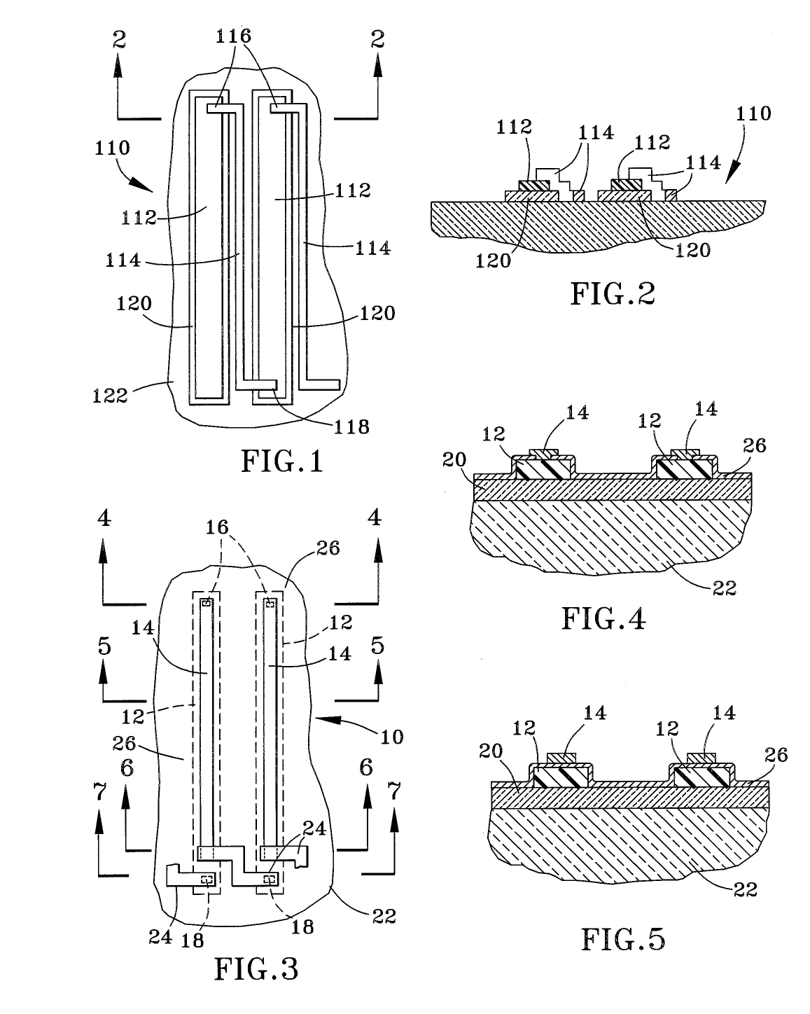

The dielectric layers 20 and 26 may be grown or deposited on the substrate surface 22 and the first conductor 12, respectively, in any suitable manner as long as the dielectric layer 26 adequately electrically insulates the first and second conductors 12 and 14 of each stack from each other except for their contact at the junction 16. The first and second conductors 12 and 14 may also be deposited in any suitable manner. The second conductors 14 are preferably deposited to have thicknesses of less than the first conductors 12 and slightly greater than the dielectric layer 26. Notably, because they are not required to traverse the steps defined by the dielectric layer 26 and conductor 12, the second conductors 14 can be less than one-third the thickness of conductors used in traditional side-by-side thermocouple arrangements (e.g., the conductors 114 of FIG. 1). As a result, the heat loss through the second conductors 14 can be reduced by at least a factor of three, resulting in a higher output signal for the thermocouple structure 10.

In addition to increased output and reliability, another advantage of the stacked thermocouple structure 10 of FIGS. 3 through 7 is the ability to pack more thermocouple pairs in a given area than traditional side-by-side structures, thereby further promoting the generation of a higher output signal. For example, if the thermocouple structure 10 is part of a thermopile of an infrared sensor, an absorber area of about 1.2×1.2 mm² can be defined to accommodate about 276 pairs of stacked thermocouples of this invention, as opposed to about 228 pairs of a traditional side-by-side thermocouple structure. Second conductors 14 formed of aluminum can be formed to have thicknesses of as little as about 0.1 micrometer, whereas aluminum lines of a side-by-side structure (e.g., FIG. 1) must typically be at least 0.35 micrometer thick to avoid reliability problems. In comparison, the thicker connectors 24 at the cold junctions 18 of the stacked structure 10 can be about 1 micrometer in thickness to promote the reliability of the connection. According to one embodiment of the invention, an infrared (IR) sensor with the stacked thermocouple structure 10 of the type shown in FIG. 3 can have an overall output of about 105 μV/K, as compared to an output of about 78 μV/K for essentially an identical sensor fabricated to have a side-by-side thermocouple structure. Accordingly, the present invention is capable of providing an approximately 34% higher output than an otherwise identical sensor.

While the invention has been described in terms of a preferred embodiment, it is apparent that other forms could be adopted by one skilled in the art. Accordingly, the scope of the invention is to be limited only by the following claims.

1. A stacked thermocouple structure comprising:
a plurality of first conductors on a surface and formed of a first material, each of the first conductors having first and second ends and a thickness in a direction normal to the surface;
a dielectric layer on each of the first conductors;
a plurality of second conductors on the dielectric layer and formed of a second material that differs from the first material, each of the second conductors having a thickness in a direction normal to the surface, a first end overlying and contacting the first end of the corresponding first conductor, and a second end overlying but separated from the second end of the corresponding first conductor by the dielectric layer; and
a plurality of third conductors, each of the third conductors electrically interconnecting the second end of one of the second conductors with the second end of one of the first conductors other than the first conductor on which the second conductor lies, each of the third conductors having a thickness in a direction normal to the surface that is greater than the thickness of the second conductors.

2. The stacked thermocouple structure according to claim 1, wherein the third conductors are formed of the second material.

3. The stacked thermocouple structure according to claim 1, wherein the dielectric layer has a thickness in a direction normal to the surface that is less than the thicknesses of the second conductors.

4. The stacked thermocouple structure according to claim 1, wherein the thicknesses of the third conductors are more than three times greater than the thicknesses of the second conductors.

5. The stacked thermocouple structure according to claim 1, wherein the third conductors and the second ends of the first and second conductors define cold junctions of the stacked thermocouple structure.

6. The stacked thermocouple structure according to claim 1, wherein the first material is polysilicon and the second material is aluminum

7. The stacked thermocouple structure according to claim 1, wherein the first and second conductors define steps that are traversed by the third conductors.

8. The stacked thermocouple structure according to claim 1, wherein the surface is defined by a second dielectric layer on a substrate and each of the first conductors is on the second dielectric layer.

9. The stacked thermocouple structure according to claim 8, wherein the second conductors have lateral widths less than lateral widths of the first conductors so as to define steps from the substrate to the second conductors, the steps being traversed by the third conductors.

10. The stacked thermocouple structure according to claim 1, wherein the stacked thermocouple structure is a thermopile that produces an output dependent on a temperature difference between the first and second ends of the first and second conductors.

11. The stacked thermocouple structure according to claim 10, wherein the thermopile is a component of a thermal sensor package.

12. A stacked thermocouple structure of a thermopile that produces an output dependent on a temperature difference between hot and cold junctions of the thermopile, the stacked thermocouple structure comprising:
a plurality of first conductors on a surface and formed of a first material, each of the first conductors having first and second ends and a thickness in a direction normal to the surface;
a dielectric layer on each of the first conductors;
a plurality of second conductors on the dielectric layer and formed of a second material that differs from the first material, each of the second conductors having a thickness in a direction normal to the surface, a first end overlying and contacting the first end of the corresponding first conductor to define one of the hot junctions of the thermopile, and a second end overlying but separated from the second end of the corresponding first conductor by the dielectric layer; and
a plurality of third conductors formed of the second material, each of the third conductors electrically interconnecting one of the second ends of the second conductors with one of the second ends of the first conductors to define one of the cold junctions of the thermopile, each of the third conductors having a thickness in a direction normal to the surface that is greater than the thickness of the second conductors.

13. The stacked thermocouple structure according to claim 12, wherein the dielectric layer has a thickness in a direction normal to the surface that is less than the thicknesses of the second conductors.

14. The stacked thermocouple structure according to claim 12, wherein the thicknesses of the third conductors are more than three times greater than the thicknesses of the second conductors.

15. The stacked thermocouple structure according to claim 12, wherein the first material is polysilicon and the second material is aluminum.

16. The stacked thermocouple structure according to claim 12, wherein the thermopile is a component of a thermal sensor package.

17. The stacked thermocouple structure according to claim 12, wherein the first and second conductors define steps that are traversed by the third conductors.

18. The stacked thermocouple structure according to claim 12, wherein the surface is defined by a second dielectric layer on a substrate and each of the first conductors is on the second dielectric layer

19. The stacked thermocouple structure according to claim 18, wherein the second conductors have lateral widths less than lateral widths of the first conductors so as to define steps from the substrate to the second conductors, the steps being traversed by the third conductors.

20. The stacked thermocouple structure according to claim 12, wherein the thermopile is a component of a thermal sensor package.
